(19) United States
(12) Patent Application Publication
(10) Pub. No.: US 2014/0332059 A1
(43) Pub. Date: Nov. 13, 2014

(54) SOLAR PANEL MOUNTING SYSTEMS AND METHODS

(71) Applicant: Suniva, Inc., Norcross, GA (US)

(72) Inventors: Stephen Patrick Shea, Savannah, GA (US); Gregory Tyrone Jones, Atlanta, GA (US)

(73) Assignee: Suniva, Inc., Norcross, GA (US)

(21) Appl. No.: 14/273,793

(22) Filed: May 9, 2014

Related U.S. Application Data
(60) Provisional application No. 61/821,460, filed on May 9, 2013.

(51) Int. Cl. H01L 31/042

(52) U.S. Cl. CPC H01L 31/0422; H02S 20/00
USPC 136/251; 211/41.1

(57) ABSTRACT

A mounting system for mounting a plurality of solar panels is provided. In one aspect, the mounting system has plurality of panel modules and at least one of: a means for selectively securing a pair of adjacently positioned panel modules to a support structure in an edge-to-edge relationship along a mounting axis that is transverse to the coupling axis, and a means for selectively locking a distal end of one pair of mounting members of one panel module to a proximal end of another pair of mounting members of an adjoining panel module to form at least a portion of one coupled panel module that is adjoined end-to-end along a coupling axis that is transverse to the mounting axis.

### CROSS REFERENCE TO RELATED APPLICATION

This application claims the benefit of U.S. Provisional Application No. 61/821,460, filed May 9, 2013, which is hereby incorporated herein by reference in its entirety.

### FIELD OF THE INVENTION

This invention relates generally to systems and methods for mounting solar panels to an underlying structure. More specifically, mounting systems and methods are provided for robustly mounting solar panels with a reduced number of anchoring devices.

### BACKGROUND OF THE INVENTION

A conventional photovoltaic panel array includes a plurality of solar panels arranged for converting light incident upon the panels to electricity. These solar panels are typically attached or mounted with a panel mounting system to a roof of a structure, a ground rack or a tracking unit. Conventional panel mounting systems are costly, heavy, and labor intensive to install. For example, conventional mounting systems can require meticulous on-site assembly of mechanically complicated parts performed by expensive field labor. The on-site assembly can therefore be time consuming, which can be made worse because on-site assembly is often performed in unfavorable working conditions without the benefit of quality control safeguards and precision tooling.

Because of the difficulty in on-site assembly of conventional panel mounting systems, misalignment of the overall panel mounting assembly often occurs. This can jeopardize the supported solar panels, or other supported devices. For example, spacing of the solar panels is important to accommodate expansion and contraction due to the change of the weather. It can be difficult, however, to precisely space the panels on-site using conventional panel mounting systems without expensive technical assistance.

Further, conventional panel mounting systems can require one or more penetrations of the underlying support structure per panel. For example, a roof-mounted array of twelve panels can conventionally require twelve to sixteen roof penetrations. Each penetration is time consuming and can cause damage to the underlying structure. Each penetration can also provide an undesirable entry point into the underlying structure for water. Thus, there is a need in the art for improved panel mounting systems that is easy to install and reduces the number of penetrations of the underlying structure.

### SUMMARY OF THE INVENTION

In accordance with the purpose(s) of this invention, as embodied and broadly described herein, this invention, in one aspect, relates to mounting systems and methods for mounting a plurality of solar panels to an underlying structure.

In one aspect, a mounting system for mounting a plurality of solar panels can comprise a plurality of panel modules and at least one of: a means for selectively securing a pair of adjacently positioned panel modules to a support structure in an edge-to-edge relationship along a mounting axis that is transverse to the coupling axis, and a means for selectively locking a distal end of one pair of mounting members of one panel module to a proximal end of another pair of mounting members of an adjoining panel module to form at least a portion of one coupled panel module that is adjoined end-to-end along a coupling axis that is transverse to the mounting axis.

In one aspect, each panel module can comprise a pair of elongate opposed mounting members that are configured to be arranged and secured spaced apart and substantially parallel to one another. In a further aspect, each of the mounting members can be configured to receive and support an edge region of a solar panel such that one solar panel extends between the pair of opposed mounting members.

In one aspect, the means for selectively securing a pair of adjacently positioned panel modules to a support structure can comprise at least one anchoring device that is configured to selectively secure a pair of adjacently positioned panel modules to an underlying support structure in an edge-to-edge relationship along a mounting axis. In this aspect, each anchoring device can comprise a footing adapted to be rigidly fastened to the underlying support structure and a biasable support member having opposed outer ends. The biasable support member can be configured for selective connection with a portion of respective outer mounting members of the pair of adjacently positioned panel modules.

In one aspect, and not meant to be limiting, the means for selectively locking a distal end of one pair of mounting members of one panel module to a proximal end of another pair of mounting members of an adjoining panel module can comprise a selective locking mechanism.

In one aspect, the selective locking mechanism can comprise at least one of: an elongate trough, a first elongate slot, a second slot, and a mating bar. In this aspect, it is contemplated that the elongate trough can extend the substantial elongate length of each mounting member. The first elongate slot can extend longitudinally inwardly from a distal end of the mounting member and the second slot can have a first slot portion extending upwardly therefrom a bottom edge of the mounting member and a second slot portion extending longitudinally inwardly from an end of the first slot portion. In this aspect, the second slot can be spaced a predetermined distance from the first slot and can be positioned between the first slot and a proximal end of the first slot.

In a further aspect, the mating bar can be configured to be selectively and fixedly received therein a portion of the trough of a mounting member. In one aspect, each mating bar can be configured with a pair of spaced first male protrusions that extend outwardly from an outer surface of the mating bar. In this aspect, each first male protrusion of the mating bar can be configured to be selectively received therein the first and second slots of an adjoining mounting member.

In yet another exemplary aspect, the selective locking mechanism can further comprise at least one of: a third elongate slot extending longitudinally inwardly from a proximal end of the mounting member and a fourth slot having a third slot portion extending upwardly therefrom a bottom edge of the mounting member and a fourth slot portion extending longitudinally inwardly from an end of the third slot portion. In this aspect, the fourth slot can be spaced the predetermined distance from the third slot and can be positioned between the third slot and a distal end of the first slot. In this aspect, it is contemplated that the mating bar can further comprise a pair of spaced second male protrusions extending outwardly from the outer surface of the mating bar. Each second male protrusion of the mating bar being configured to be selectively received therein the third and fourth slots of another mounting member.

Additional advantages of the invention will be set forth in part in the description which follows, and in part will be obvious from the description, or may be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate several aspects of the invention and together with the description, serve to explain the principles of the invention.

FIG. 1 is an exploded top perspective view of one embodiment of a mounting system comprising a mounting member, a biasable support member, and an attachment device.

FIG. 2 is a perspective view of the mounting member of FIG. 1.

FIG. 3 is bottom perspective view of the mounting system of FIG. 1.

FIG. 4 is a top perspective view of a mating bar of a mounting system, according to one aspect.

FIG. 5 is a bottom perspective view of a portion of a panel module of a mounting system, according to one aspect.

FIG. 6 is a bottom perspective view of the mounting system with a plurality of panel modules coupled thereto.

FIG. 7 is a top perspective view of the mounting system of FIG. 1, showing one panel module, according to one aspect.

FIGS. 8-11 illustrate exemplary steps to couple a plurality of panel modules together, according to one aspect.

FIG. 12 is a perspective view of a second embodiment of the mounting system comprising a plurality of cell rails, a plurality of frame members, and a plurality of attachment devices.

FIG. 13 is a top elevational view of the mounting system of FIG. 12.

FIG. 14 is a bottom side elevational view of the mounting system of FIG. 12.

FIG. 15 is a side elevational view of the mounting system of FIG. 12.

FIG. 16 is an enlarged perspective view of a corner portion of the formed mounting system of FIG. 12.

FIG. 17 is an elevational view of the corner portion of the formed mounting system of FIG. 16.

FIG. 18 is an enlarged perspective view of a center portion of the formed mounting system of FIG. 12.

FIG. 19 is an elevational view of the center portion of the formed mounting system of FIG. 18.

### DESCRIPTION OF THE PREFERRED EMBODIMENTS

The present invention may be understood more readily by reference to the following detailed description, examples, drawings, and claims, and their previous and following description. However, before the present devices, systems, and/or methods are disclosed and described, it is to be understood that this invention is not limited to the specific devices, systems, and/or methods disclosed unless otherwise specified, as such can, of course, vary. It is also to be understood that the terminology used herein is for the purpose of describing particular aspects only and is not intended to be limiting.

The following description of the invention is provided as an enabling teaching of the invention in its best, currently known embodiment. To this end, those skilled in the relevant art will recognize and appreciate that many changes can be made to the various aspects of the invention described herein, while still obtaining the beneficial results of the present invention. It will also be apparent that some of the desired benefits of the present invention can be obtained by selecting some of the features of the present invention without utilizing other features. Accordingly, those who work in the art will recognize that many modifications and adaptations to the present invention are possible and can even be desirable in certain circumstances and are a part of the present invention. Thus, the following description is provided as illustrative of the principles of the present invention and not in limitation thereof.

As used throughout, the singular forms “a,” “an” and “the” include plural referents unless the context clearly dictates otherwise. Thus, for example, reference to “a module” can include two or more such modules unless the context indicates otherwise.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

As used herein, the terms “optional” or “optionally” mean that the subsequently described event or circumstance may or may not occur, and that the description includes instances where said event or circumstance occurs and instances where it does not.

The present invention may be understood more readily by reference to the following detailed description of preferred embodiments of the invention and the examples included therein and to the Figures and their previous and following description.

In one broad aspect, the present invention comprises mounting systems and methods for mounting a plurality of solar panels.

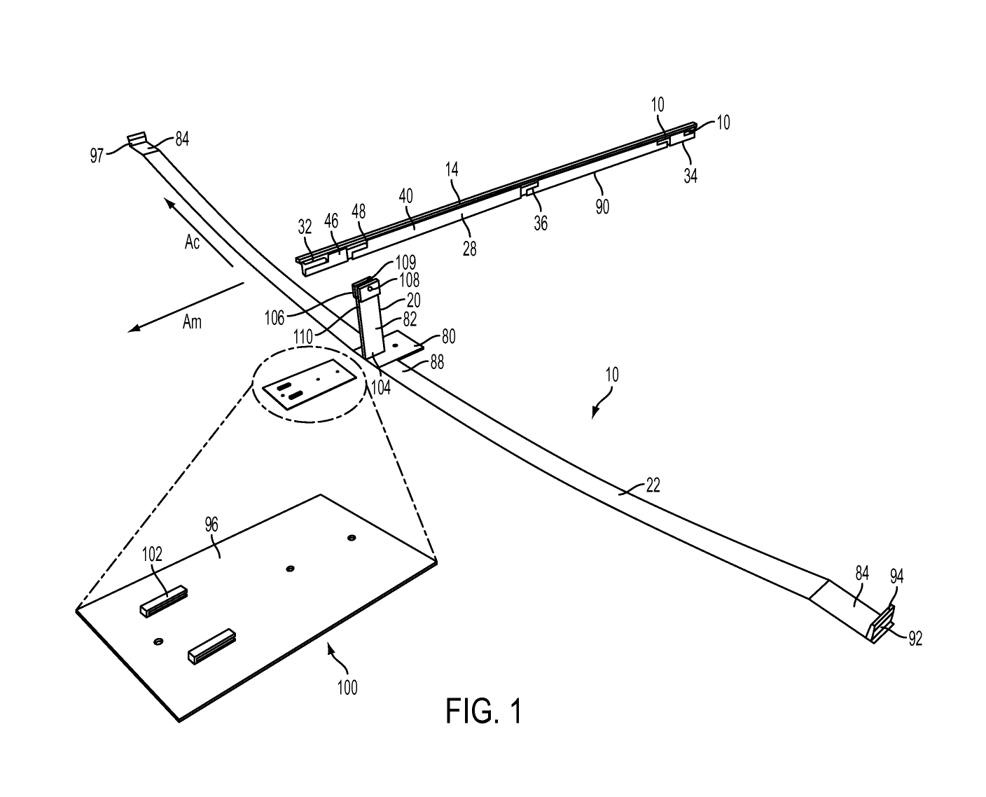

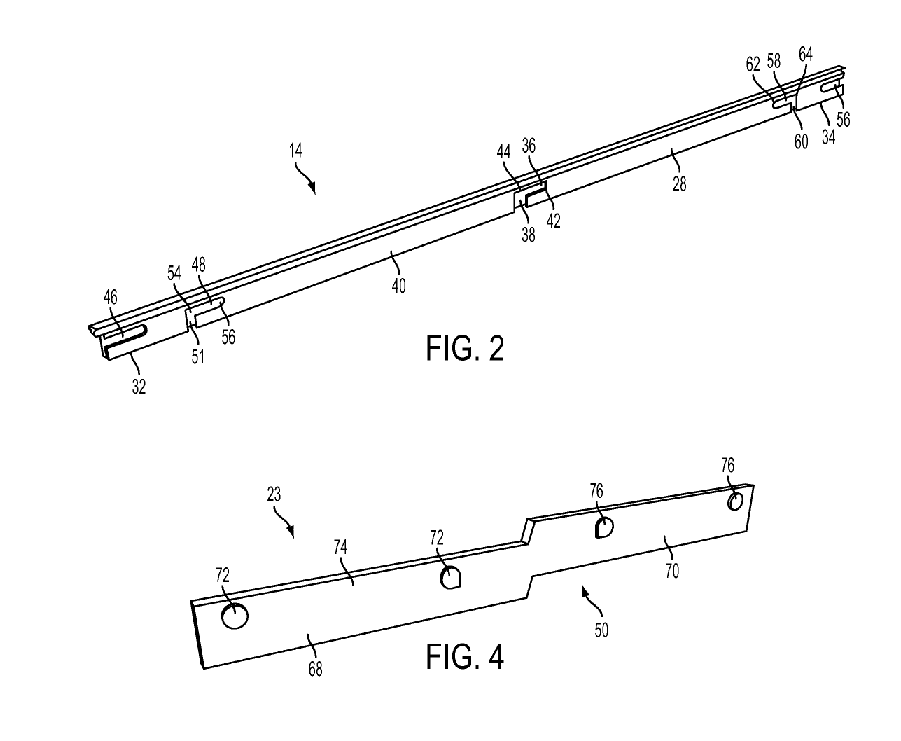

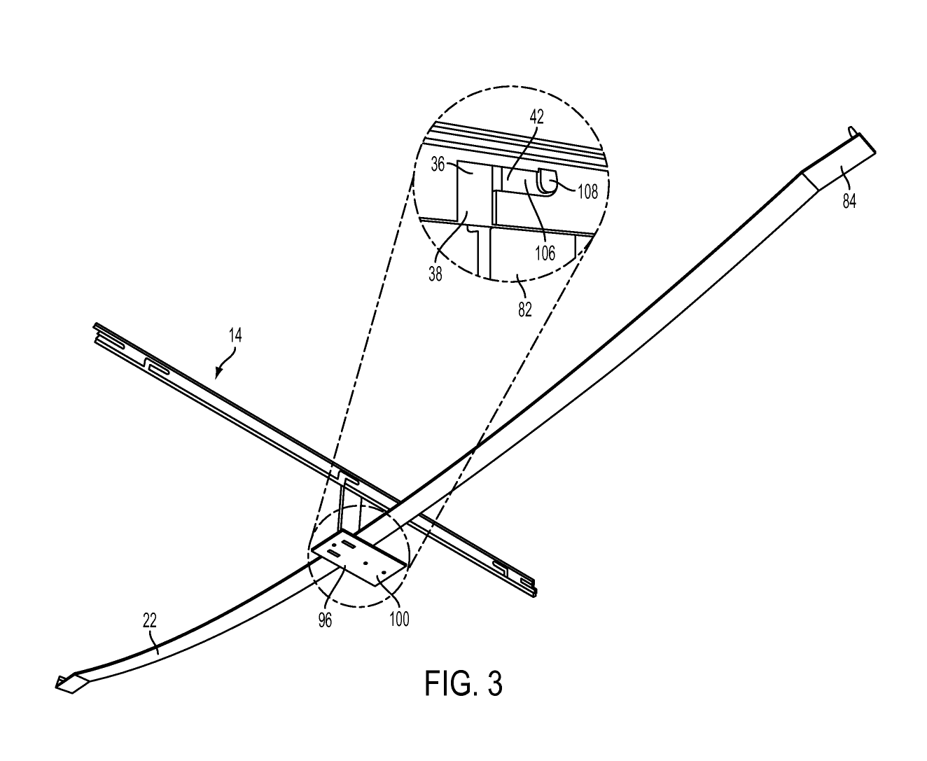

With reference to FIGS. 1-6, in one aspect, the mounting system 10 comprises a plurality of panel modules 12, each panel module comprising a pair of elongate opposed mounting members 14. In another aspect, each mounting member can be configured to receive and support an edge region 16 of a solar panel 18. In this aspect, at least one solar panel can be positioned to and extend between the pair of opposed mounting members.

In another aspect, the mounting system comprises at least one of a means for selectively securing a pair of adjacently positioned panel modules 12 in an end-to-end relationship along a coupling axis, and a means for selectively securing a pair of adjacently positioned panel modules 12 to a support structure in an edge-to-edge relationship along a mounting axis that is transverse to the coupling axis. In another aspect, the mounting system and/or the means for selectively securing a pair of adjacently positioned panel modules in an end-to-end relationship and in an edge-to-edge relationship can comprise at least one of: at least one anchoring device 20, a biasable support member 22, and a selective locking mechanism 23.

In one aspect, the pair of elongate opposed mounting members 14 can be arranged and/or secured spaced apart from each other a predetermined distance. For example, the mounting members can be spaced a predetermined distance corresponding to the width of a solar panel 18. Alternatively, the predetermined distance can be slightly greater than or slightly less than the width of a solar panel. In another aspect, the mounting members 14 can be arranged and/or secured substantially parallel to one another. Optionally, the mounting members can be arranged and/or secured at an acute angle relative to each other. In another option, a bracing member can be coupled to and extend therebetween the respective pair of opposed mounting members to provide a desired degree of mechanical support.

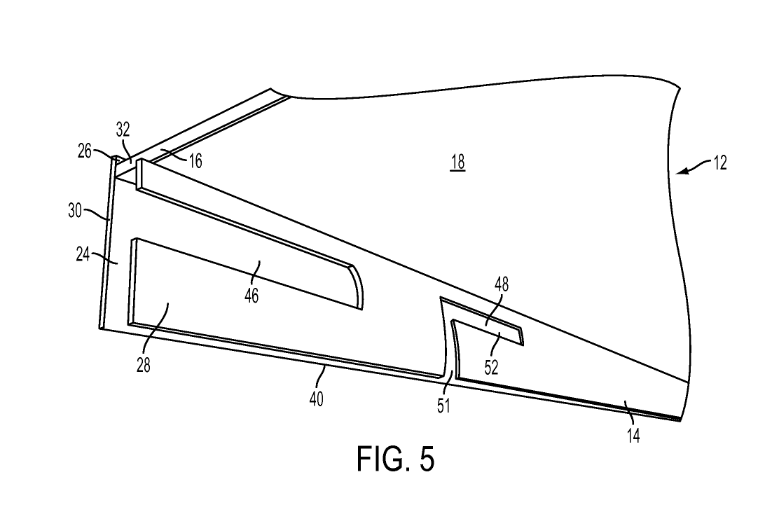

In one aspect, and with reference to FIG. 5, an elongate trough 24 can be defined in each mounting member 14. In this aspect, the trough can be defined by a top wall 26, an inner side wall 28 and an outer side wall 30. For example, when viewed in cross section, each mounting member can be substantially “U” shaped, substantially “C” shaped, and the like. In another aspect, the inner side wall can be substantially parallel to the outer side wall. In a further aspect, the elongate trough can extend the substantial elongate length of the mounting member. That is, the elongate trough 24 can extend from a proximal end 32 to a distal end 34 of each mounting member 14.

In one aspect, at least one coupling slot 36 can be defined in each mounting member 14. According to another aspect, the at least one coupling slot can be positioned between the distal and proximal ends 32, 34 of the mounting member. The at least one coupling slot 36 can be defined in the inner side wall 28 and/or the outer side wall 30 of the mounting member. In a further aspect, the at least one coupling slot can have a first coupling slot portion 38 extending upwardly therefrom a bottom edge 40 of the mounting member and a second coupling slot portion 42 extending longitudinally from an end 44 of the first coupling slot portion. In this aspect, the first coupling slot portion can extend upwardly therefrom the bottom edge substantially normal to the bottom edge 40. Optionally, the first coupling slot portion 38 can extend upwardly therefrom the bottom edge at an acute angle relative to the bottom edge 40. In another aspect, the second coupling slot portion 42 can be substantially parallel to the bottom edge of the mounting member 14. Optionally, the second coupling slot portion can be at an acute angle relative to the bottom edge 40 of the mounting member.

Each mounting member 14 can be configured for selective longitudinal attachment to another mounting member, according to one aspect. In this aspect, the mounting system can further comprise a means for selectively locking a distal end 34 of one pair of mounting members 14 of one panel module 12 to a proximal end 32 of another pair of mounting members of an adjoining panel module to form at least a portion of one coupled panel module. That is, each mounting member 14 of a pair of opposed mounting members can be joined end-to-end along a coupling axis to a second pair of opposed mounting members.

In one aspect, the means for selectively locking a distal end 34 of one pair of mounting members 14 of one panel module 12 to a proximal end 32 of another pair of mounting members of an adjoining panel module to form at least a portion of one coupled panel module comprises the selective locking mechanism 23. In another aspect, the selective locking mechanism 23 comprises at least one of the elongate trough 24, a first elongate slot 46, a second slot 48, and a mating bar 50.

The first elongate slot 46 can be a slot defined in the inner side wall 28 and/or the outer side wall 30 of the mounting member 14. In one aspect, the first elongate slot can extend longitudinally inwardly from the distal end 34 of the mounting member. In another aspect, the first elongate slot 46 can be substantially parallel to the bottom edge 40 of the mounting member 14. Optionally, the first elongate slot 46 can be at an acute angle relative to the bottom edge of the mounting member.

In one aspect, the second slot 48 can be defined in the inner side wall 28 and/or the outer side wall 30 of the mounting member 14. In a further aspect, the second slot can have a first slot portion 51 extending upwardly therefrom a bottom edge 40 of the mounting member and a second slot portion 52 extending longitudinally from an end 54 of the first slot portion. As can be appreciated, the second slot can be substantially “L” shaped. In this aspect, the first slot portion 51 can extend upwardly therefrom the bottom edge substantially normal to the bottom edge 40. Optionally, the first slot portion 51 can extend upwardly therefrom the bottom edge at an acute angle relative to the bottom edge 40. In another aspect, the second slot portion 52 can be substantially parallel to the bottom edge of the mounting member 14. Optionally, the second slot portion can be at an acute angle relative to the bottom edge 40 of the mounting member. In another aspect, the second slot 48 can be positioned between the first elongate slot 46 and the proximal end 32 of the mounting member. In still another aspect, the second slot can be spaced from the first slot a predetermined distance.

In other aspects, the locking mechanism 23 can further comprise a third elongate slot 56 and a fourth slot 58. In one aspect, the third elongate slot 56 can be a slot defined in the inner side wall 28 and/or the outer side wall 30 of the mounting member 14. In one aspect, the third elongate slot can extend longitudinally inwardly from the proximal end 32 of the mounting member. In another aspect, the third elongate slot 56 can be substantially parallel to the bottom edge 40 of the mounting member 14. Optionally, the third elongate slot 56 can be at an acute angle relative to the bottom edge of the mounting member.

In one aspect, the fourth slot 58 can be defined in the inner side wall 28 and/or the outer side wall 30 of the mounting member 14. In a further aspect, the fourth slot can have a third slot portion 60 extending upwardly therefrom a bottom edge 40 of the mounting member and a fourth slot portion 62 extending longitudinally from an end 64 of the third slot portion. As can be appreciated, the fourth slot can be substantially “L” shaped. In this aspect, the third slot portion 60 can extend upwardly therefrom the bottom edge substantially normal to the bottom edge 40. Optionally, the third slot portion 60 can extend upwardly therefrom the bottom edge at an acute angle relative to the bottom edge 40. In another aspect, the fourth slot portion 62 can be substantially parallel to the bottom edge of the mounting member 14. Optionally, the fourth slot portion can be at an acute angle relative to the bottom edge 40 of the mounting member. In another aspect, the fourth slot 58 can be positioned between the third elongate slot 56 and the second slot 48. Optionally, in another aspect, the fourth slot can be spaced from the third slot a predetermined distance that can be the same as, less than or greater than the predetermined distance between the first slot 46 and the second slot 48.

In still another aspect, at least two of the first elongate slot 46, the third elongate slot 56, the second slot portion 52, the fourth slot portion 62 and the second coupling slot portion 42 can be substantially parallel to each other. In a further aspect, the first elongate slot 46, the third elongate slot 56, the second slot portion 52, the fourth slot portion 62 and/or the second coupling slot portion 42 can be substantially parallel to and co-axially aligned with each other.

In one aspect, the mating bar 50 can be configured to be selectively fixedly received therein a portion of the trough 24 of a mounting member 14. That is, the mating bar can be sized and shaped to fit into a portion of the trough. For example, the mating bar 50 can have a mating bar thickness that is equal to or slightly less than the distance between the inner and outer side walls 28, 30 of the mating member 14. In another example, the mating bar 50 can have a mating bar height that is equal to or slightly less than the depth of the trough 24.

The mating bar 50 can have a first elongate portion 68 and a second elongate portion 70, according to one aspect. In another aspect, the first elongate portion can be parallel to the second elongate portion. In still another aspect, an elongate axis A₁ of the first elongate portion can be offset from an elongate axis A₂ of the second elongate portion by a predetermined offset distance. For example, the predetermined offset distance can be about 0.25 inches, about 0.50 inches, about 0.75 inches, about 1 inch or greater than about 1 inch. Alternatively, the predetermined offset distance can be about 0 inches such that the elongate axis A₁ of the first elongate portion 68 is substantially co-axially aligned with the elongate axis A₂ of the second elongate portion 70.

In one aspect, the mating bar 50 can comprise at least a pair of spaced first male protrusions 72 extending outwardly from an outer surface 74 of the mating bar. In this aspect, each first male protrusion of the mating bar 50 can be configured to be selectively received therein the first elongate slot 46 and second slots 48 of an adjoining mounting member 14. That is, each first male protrusion 72 can be configured to form an interference fit with a portion of at least one of the first and second slots 46, 48 of the mounting member when the mating bar is positioned in a coupled position with the mounting member 14. In another aspect, the first male protrusion that is configured to be received in the second slot can be configured to form an interference fit with a portion of the second slot portion 52 when the mating bar is positioned in the coupled position with a mounting member.

In one aspect, the mating bar 50 can further comprise at least a pair of spaced second male protrusions 76 extending outwardly from the outer surface 74 of the mating bar. In this aspect, each second male protrusion of the mating bar 50 can be configured to be selectively received therein the third elongate slot 56 and fourth slot 58 of a mounting member 14. That is, each second male protrusion 76 can be configured to form an interference fit with a portion of at least one of the third and fourth slots 56, 58 of the mounting member when the mating bar 50 is positioned in a coupled position with the mounting member 14. In another aspect, the second male protrusion that is configured to be received in the fourth slot can be configured to form an interference fit with a portion of the fourth slot portion 62 when the mating bar is positioned in the coupled position with a mounting member.

The first male protrusions 72 can extend from the first elongate portion 68 of the mating bar 50 according to one aspect. In another aspect, the second spaced male protrusions 76 can extend from the first elongate portion or the second elongate portion 70 of the mating bar. In a further aspect, the first male protrusions can be offset from the second male protrusions by the predetermined offset distance.

According to one aspect, the mating bar 50 can be coupled to the proximal end 32 or the distal end 34 of a respective mounting member 14. In another aspect, the mating bar can be integrally formed to the proximal end or the distal end of the respective mounting member.

Referring now to FIG. 1, the at least one anchoring device 20 can be configured to selectively secure a pair of adjacently positioned panel modules 12 to an underlying support structure 78 in an edge-to-edge relationship along a mounting axis Aₘ. In one aspect, the mounting axis can be substantially transverse to the coupling axis A_{c}. In another aspect, the at least one anchoring device comprises at least one of: a footing 80, the biasable support member 22 and a center point support 82. As can be appreciated, the underlying support structure can be, for example and without limitation, a roof of a structure, a ground rack and a tracking unit.

The biasable support member 22 comprises opposed outer ends 84 configured for selective connection with a portion of a respective outer mounting member 86 of the pair of adjacently positioned panel modules 12, as illustrated in FIG. 5. In one aspect, a center point 88 of the support member substantially underlies a respective inner mounting member 90 of the pair of pair of adjacently positioned panel modules. Alternatively, in another aspect, the center point of the support member 22 is spaced from the respective inner mounting members of the pair of adjacently positioned panel modules 12 a predetermined distance. That is, in this aspect, the center point of the support member does not substantially underlie respective inner mounting members 90 of the pair of adjacently positioned panel modules.

Optionally, the support member 22 can be configured to receive the bracing member mounted thereto the opposing pairs of mounting members. In another aspect, the bracing member can be integral to the support member. Optionally, in further aspects, it is contemplated that the support member can comprise trussing to restrict or otherwise limit the biasability of the support member 22 to a desired degree.

In one aspect, the support member 22 can have a leaf spring shape in which the respective outer ends 84 of the support member extend upwardly with respect to the center point 88 of the support member 22. As can be appreciated, in this aspect, the respective outer ends of the support member can move under a bias constraint relative to the fixed center point of the support member. For example, a force or bias applied downwardly to an outer end of the support member 22 can move that respective outer end of the support member downwardly relative to the fixed center point 88.

In another aspect, the support member 22 comprises a support coupling member 92 positioned at the respective outer ends 84 of the support member. The support coupling member can be configured to be selectively connectable to a mounting member 14. For example, the support coupling member 92 can be configured to be selectively connectable with the respective outer mounting members 86 along a portion of the length of the respective outer mounting members. In another aspect, the support coupling member can comprise an upwardly extending tab 94. In a further aspect, each tab can be configured to be selectively fixedly received therein a portion of the trough 24 of a mounting member 14. That is, each tab 94 can be sized and shaped to fit into a portion of the trough. For example, the tab can have a tab thickness that is equal to or slightly less than the distance between the inner and outer side walls 28, 30 of the mating member 14. In another example, the tab 94 can have a tab height that is equal to or slightly less than the depth of the trough 24.

In another aspect, each tab 94 of the support coupling member 92 can comprise a tab male protrusion 95 that extends inwardly from opposing interior surfaces 97 of the tabs. In this aspect, each tab male protrusion can be configured to be selectively received therein the coupling slot 36 of an adjoining outer mounting member 86. That is, each tab male protrusion 95 can be configured to form an interference fit with a portion of the coupling slot when the support coupling member 92 is positioned in a coupled position with an outer mounting member 86. In a further aspect, each tab male protrusion can be configured to form an interference fit with a portion of the second coupling slot portion 42 when positioned in the coupled position.

The footing 80 is adapted to be rigidly fastened to the underlying support structure 78 and can couple the center point support 82 and the support member 22 to the support structure. In one aspect, the footing of the anchoring device comprises a footer plate 96. In another aspect, the footer plate can be a substantially planar plate having an upper surface 98 and a lower surface 100. In use, described more fully below, the lower surface can be positioned on the underlying structure 78 and securedly attached using conventional fasteners such as nails, screws, bolts and the like. The upper surface of the footer plate 96 can be configured for selectively fixed coupling of the center point support 82 and the support member 22. In one aspect, the footer plate 96 can comprise at least one support attachment finger 102 extending from the upper surface. In this aspect, the at least one support attachment finger can be configured for selective fixed coupling of the support member 22 to the footer plate.

In another aspect, the center point support 82 can be selectively attached to the footer plate and/or the support member with conventional fasteners such as nails, screws, bolts and the like. In a further aspect, the center point support can extend from the footer plate substantially transverse to the footer plate 96. That is, a longitudinal axis of the center point support 82 can be substantially normal to the upper surface 98 of the footer plate. Optionally, a longitudinal axis of the center point support can be at an acute angle relative to the upper surface of the footer plate 96.

In one aspect, a proximal end 104 of the center point support 82 can be coupled to the center point 88 of the support member 22 and/or the footer plate 96. The center point support can extend upwardly for selectively coupling of a distal end 106 of the center point support to the respective inner mounting members 90 of the pair of adjacently positioned panel modules 12.

In one aspect, the distal end 106 of each center point support 82 can comprise a pair of coupling male protrusions 108 that extends outwardly from the opposing exterior surfaces 110 of the center point support. In this aspect, each coupling male protrusion of the center point support 82 can be configured to be selectively received therein the coupling slot 36 of an adjoining inner mounting member 90. That is, each coupling male protrusion 108 can be configured to form an interference fit with a portion of the coupling slot when the center point support 82 is positioned in a coupled position with an inner mounting member 90. Optionally, in another aspect, each coupling male protrusion 108 of the center point support 82 can be configured to be selectively received therein the coupling slot 36 of an adjoining outer mounting member 86. In a further aspect, each coupling male protrusion can be configured to form an interference fit with a portion of the second coupling slot portion 42 when positioned in a coupled position. A groove 109 can be defined in the distal end 106 of each center point support, the groove configured to receive the outer side wall 30 of a pair of inner mounting members 90 therein.

To assemble the mounting system 10, the footing 80 of the anchor device can be rigidly fastened to the underlying support structure 78. In one aspect, the lower surface 100 of the footer plate 96 of the footing can be positioned on the support structure and securedly fastened with conventional fasteners. In one aspect, the biasable support member 22 can be coupled to the footing 80. In another aspect, the center point 88 of the biasable support member can be coupled to the footing. For example, if the footer plate 96 comprises the at least one support attachment finger 102, the support member can be coupled to the at least one support attachment finger. In another aspect, the center point support 82 can be coupled to the footing 80 with conventional fasteners. In a further aspect, the center point support can be formed integrally with the footing. Optionally, the center point support can be coupled to the center point 88 of the support member 22.

The opposed mounting members 14 can be coupled to the edge region 16 of a plurality of panels to form a plurality of panel module 12. In one aspect, the opposed mounting members can be coupled to the edge region of a solar panel such that the inner side walls 28 of the respective mounting members 14 are opposed to and facing each other. For example, the mounting members can be coupled to the edge region of the solar panels with tapes, adhesives, screws and the like.

In another aspect, a first panel module 112 can be positioned such that a coupling male protrusion 108 of the pair of coupling male protrusions of the center point support 82 is positioned in the first coupling slot portion 38 of the inner mounting member 90, and the support coupling member 92 of the support member 22 is positioned in the trough 24 of the outer mounting member 86. When the coupling male protrusion 108 reaches the end 44 of the first coupling slot portion, the panel module can be urged longitudinally so that the coupling male protrusion is positioned at the end of the second coupling slot portion 42. If the tab 94 of the support coupling member 92 comprises a tab male protrusion 95, the tab male protrusion can be positioned in the first coupling slot portion 38 of an outer mounting member 86 prior to the panel being urged longitudinally. In this aspect, the panel module 12 can then be urged longitudinally so that the coupling male protrusion 108 is positioned at the end of the second coupling slot portion 42 of an inner mounting member, and the tab male protrusion 95 is simultaneously positioned at the end of the second coupling slot portion of an outer mounting member.

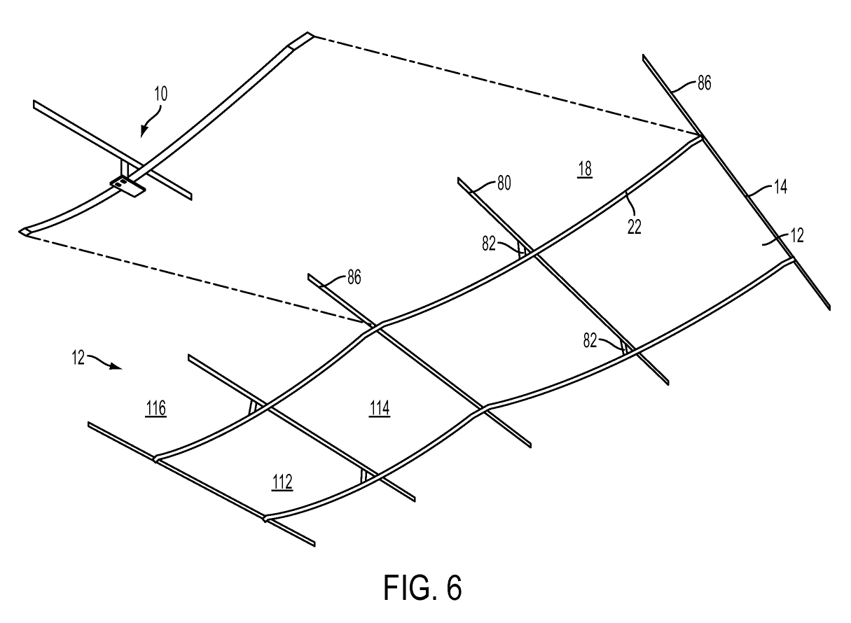

A second panel module 114 can be positioned such that the second coupling male protrusion 108 of the pair of coupling male protrusions of the center point support 82 is positioned in the first coupling slot portion 38 of the inner mounting member 90 of the second panel module, and the support coupling member 92 is positioned in the trough 24 of the outer mounting member 86. When the coupling male protrusion 108 reaches the end 44 of the first coupling slot portion, the panel module can be urged longitudinally so that the coupling male protrusion is positioned at the end of the second coupling slot portion 42. If the tab 94 of the support coupling member 92 comprises a tab male protrusion 95, the tab male protrusion can be positioned in the first coupling slot portion 38 of an outer mounting member 86 prior to the panel being urged longitudinally. In this aspect, the panel module 12 can then be urged longitudinally so that the coupling male protrusion 108 is positioned at the end of the second coupling slot portion 42 of an inner mounting member, and the tab male protrusion 95 is simultaneously positioned at the end of the second coupling slot portion of an outer mounting member. The male protrusions can form an interference fit with a portion of the respective mating slot, thereby locking the panel module in place. Thus, as illustrated in FIG. 6, the first panel module 112 and the second panel module 114 can be secured to a support structure in an edge-to-edge relationship along the mounting axis with a single attachment device 20.

Optionally, at least one additional panel module 12 can be added to the mounted pair of adjacently positioned panel modules along the coupling axis. That is, at least one additional panel module can be coupled to the proximal and/or distal ends 32, 34 of the mounting members 14.

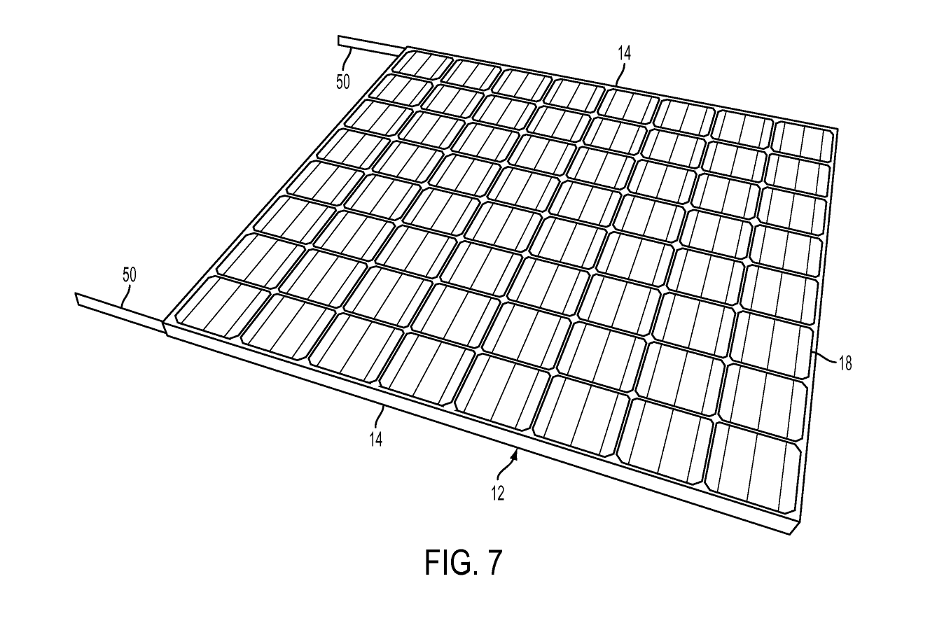

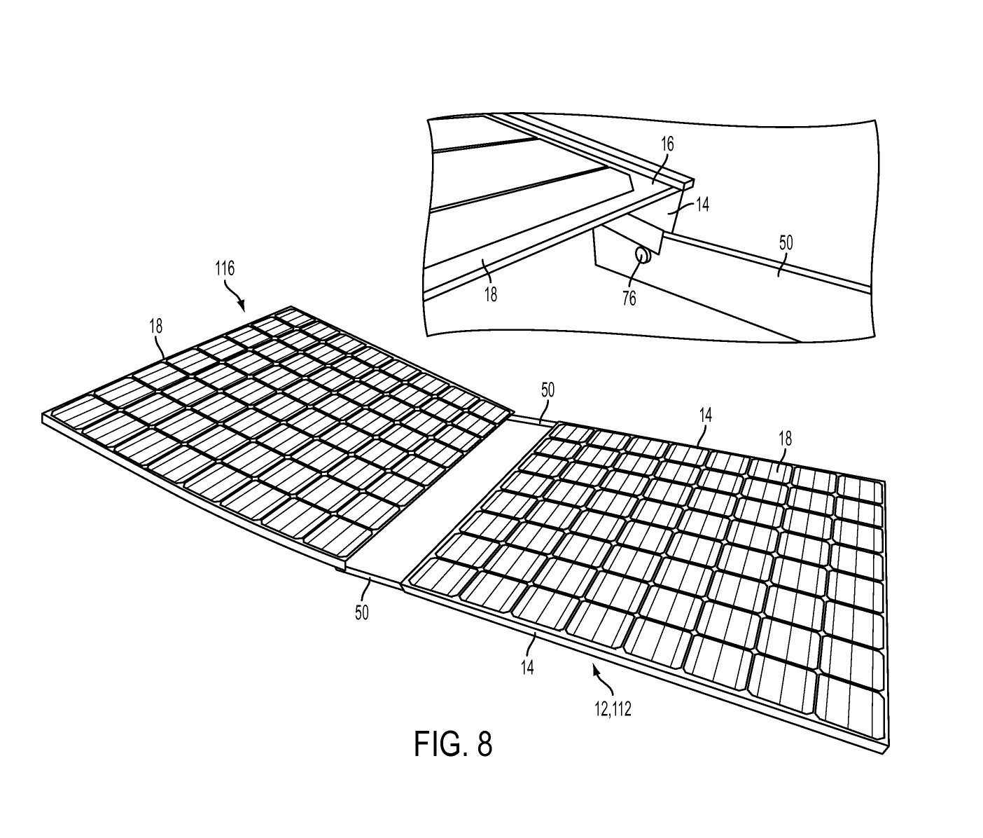

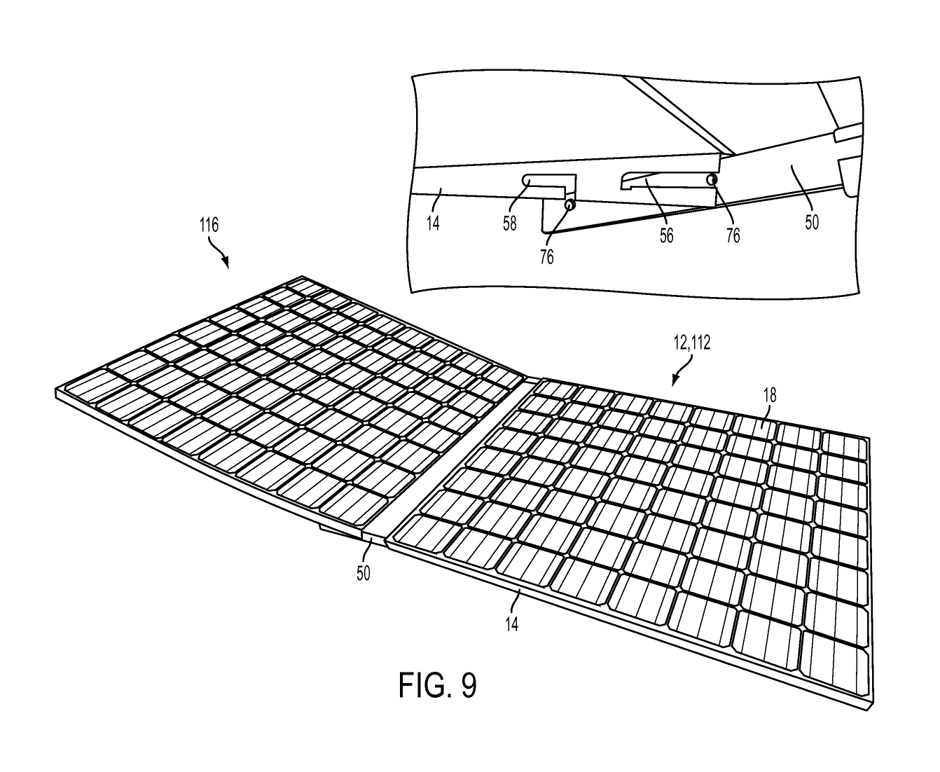

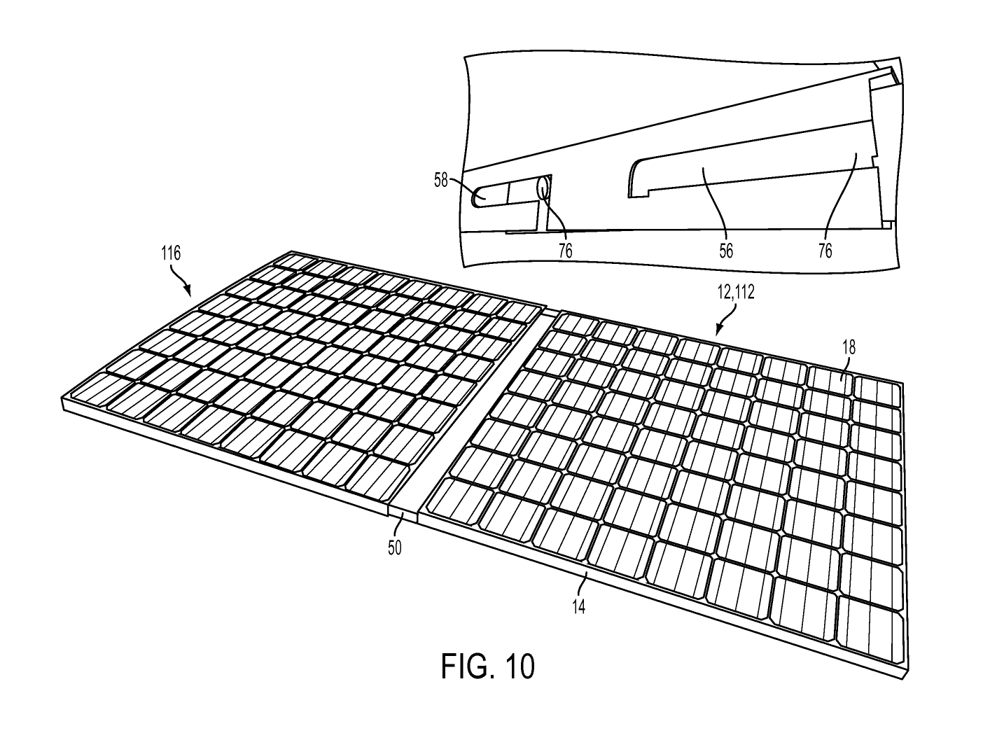

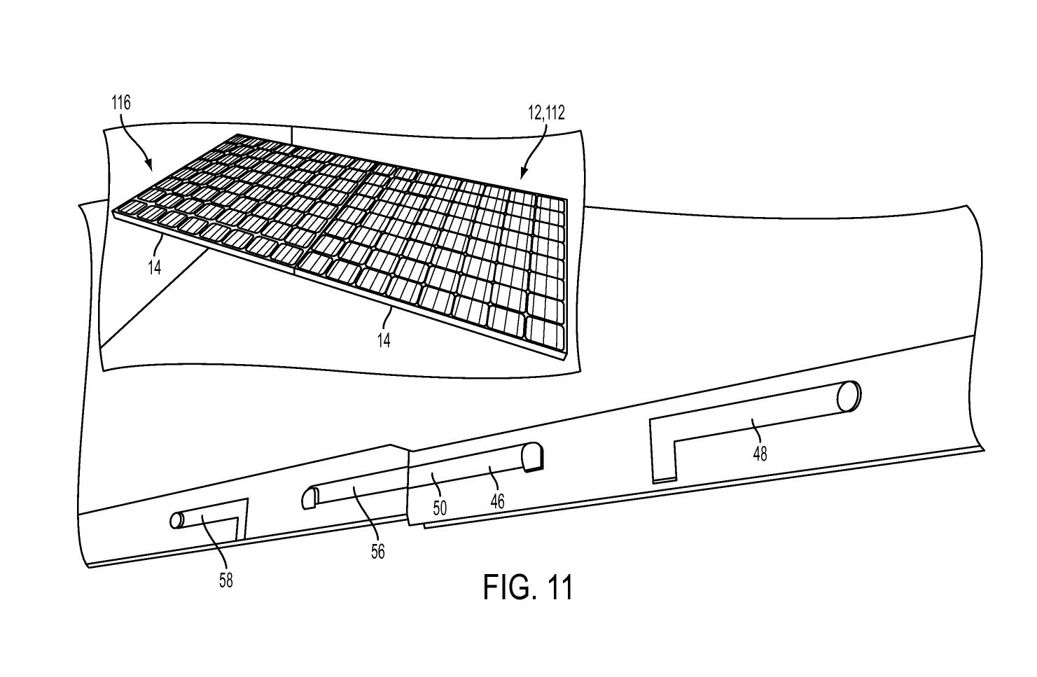

The steps to add a third panel module 116 along the coupling axis are illustrated in FIG. 7-11. In one aspect, a mating bar 50 can be selectively fixedly received therein a portion of the trough 24 of each mounting member 14 of the first panel module 112 such that the spaced first male protrusions 72 of the first elongate portion 68 of the mating bar are selectively received therein the first elongate slot 46 and second slots 48 of the mounting members of the first panel module. That is, the first male protrusion 72 can be configured to form an interference fit with a portion of at least one of the first and second slots 46, 48 of the locking mechanism when the mating bar is positioned in a coupled position with a mounting member 14.

The third panel module 116 can be positioned such that a portion of the mating bar 50 is positioned in the trough 24 of each mounting member 14 and the distal end of each mounting member 14 rests on a second spaced male protrusion 76 of the pair of second spaced male protrusions of the second elongate portion 70 of each mating bar 50. The third panel module can then be urged longitudinally toward the first panel module 112 until a spaced second male protrusion 76 of the pair of second male protrusions of each mating bar 50 is positioned adjacent the third slot portion 60 of each mounting member 14. The third panel module 116 can be lowered so that a second male protrusion of the pair of second male protrusions enters the third coupling slot portion, and a second male protrusion 76 of the pair of second male protrusions enters the fourth slot 58. When the second male protrusion reaches the end 64 of the third coupling slot portion, the panel module can be urged longitudinally so that one male protrusion of the pair of second male protrusions is positioned at the end of the third slot 56 and the other male protrusion of the pair of second male protrusions is positioned at the end of the fourth slot portion 62 of the fourth slot 58. The male protrusions can form an interference fit with a portion of the respective mating slot, thereby locking the panel module in place.

As can be appreciated, after the at least one anchoring device 20 has been attached to the support structure, the panel modules can be “snapped” together in a way that is mechanically robust and easily, selectively reversible. Further, the panel modules can be assembled by simple mechanical pressure with no tools, achieving grounding connection at the same time. Additionally, multiple panel modules can be supported by a single anchoring device 20 so that fewer penetrations of the underlying support structure 78 are required than with conventional mounting systems.

As can be appreciated, because the first elongate portion 68 and the second elongate portion 70 of the mating bars can be offset, the solar panel 18 of the third panel module 116 can be positioned higher than the solar panel of the first panel module 112. Alternatively, the solar panel of the third panel module can be positioned lower than the solar panel of the first panel module.

In one aspect, when selectively coupled, a lower edge 118 of the solar panel 18 of the third panel module 116 can overlap an upper edge 120 of the adjoined solar panel of the first panel module 112. In another aspect, the lower edge of one solar panel can be offset from the upper edge of the adjoined solar panel. In still another aspect, the offset ranges can be between about 1 mm to about 10 mm.

In one aspect, the lower edge 118 of the solar panel 18 comprises unframed glass to allow the panel to be self-cleaning by removing the frame which can trap water and debris. In another aspect, a lower edge of at least one mounting member 14 can define a drain opening to prevent water from accumulating in the trough of the mounting member.

In one aspect, an electrical junction bus can be formed at each end of the solar panel 18. In this aspect, the junction bus comprises one or more of a string-to-string bus, a bypass diode; a DC-to-DC converter or optimizer, or a DC-to-AC inverter. In another aspect, the junction bus can be injected modeled directly into the solar panel. Optionally, in another aspect, the junction bus can be incorporated into the at least one of the mounting members 14. In a further aspect, each panel module 12 further comprises a sub-array wiring assembly that is electrically coupled to the junction bus. In yet another aspect, at least a portion of the sub-array wiring assembly for each panel module 12 is substantially enclosed in an inner cavity defined in at least one of the mounting members 14. In another aspect, respective ends of the sub-array wiring assembly of respective adjoined panel modules can be configured to be releasable and selectively electrically coupled.

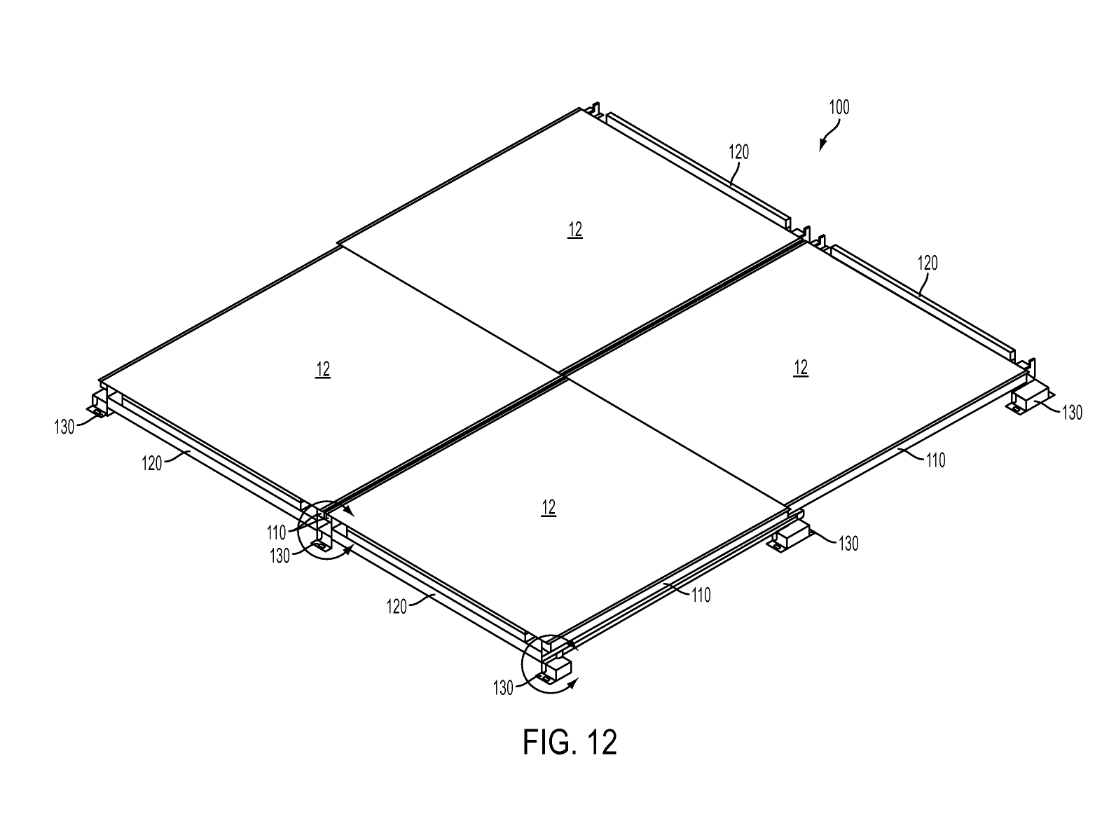

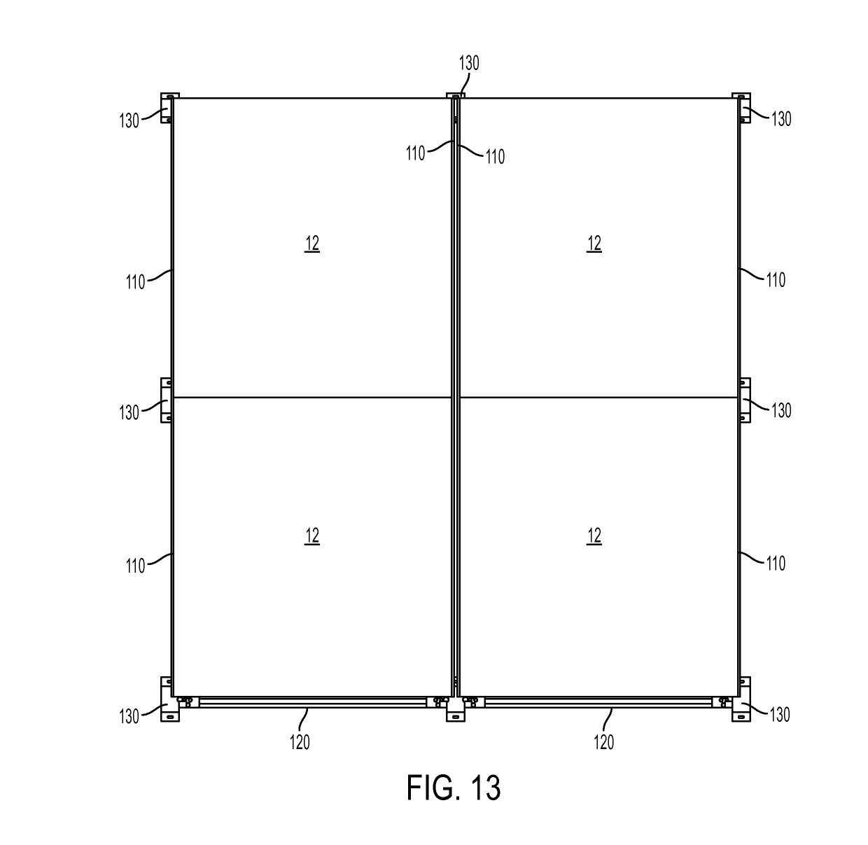

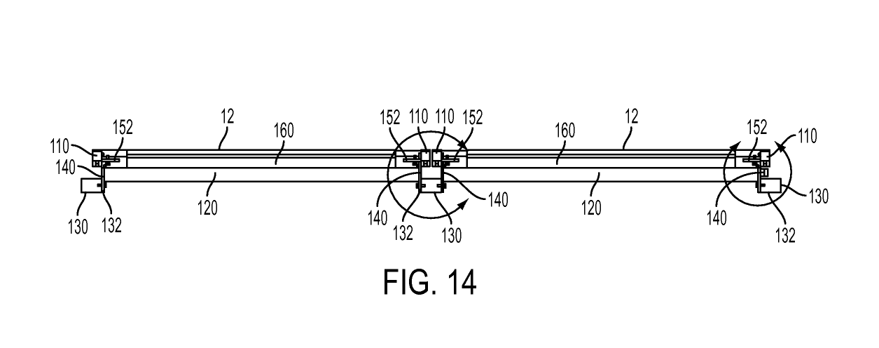

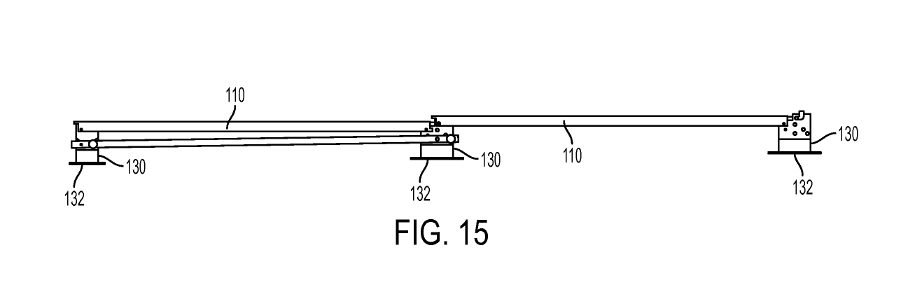

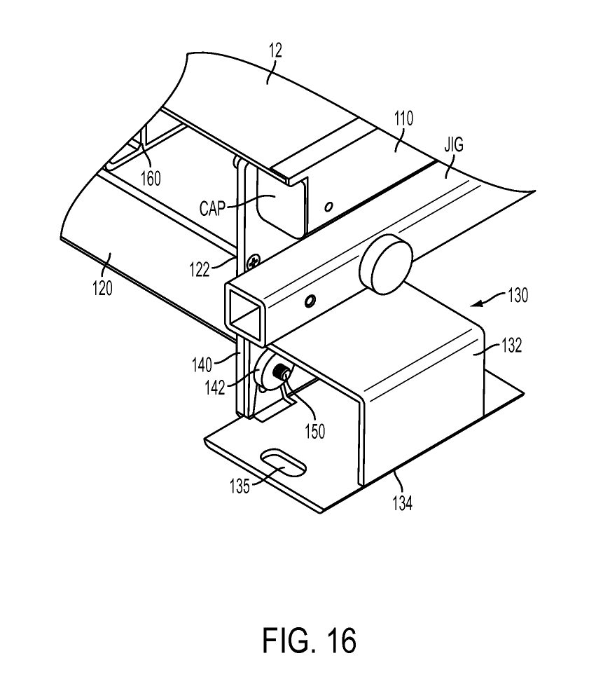

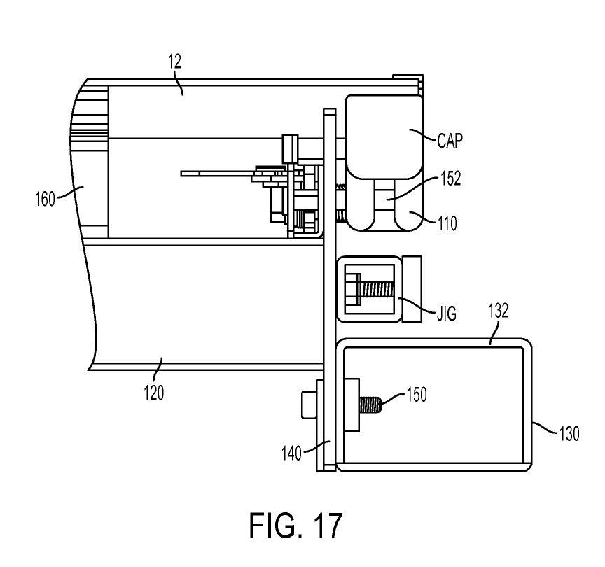

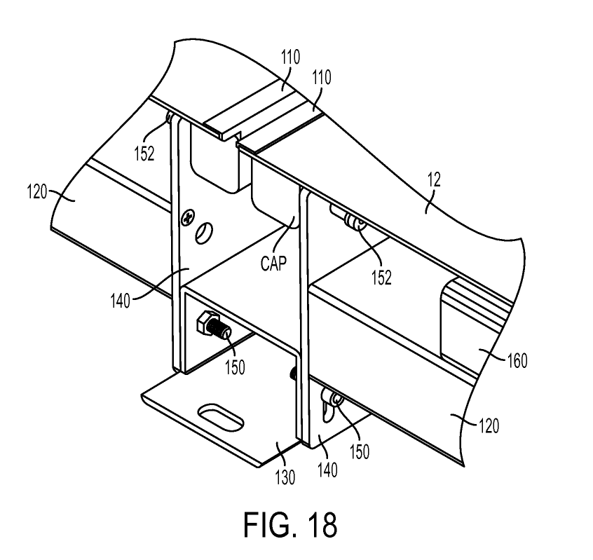

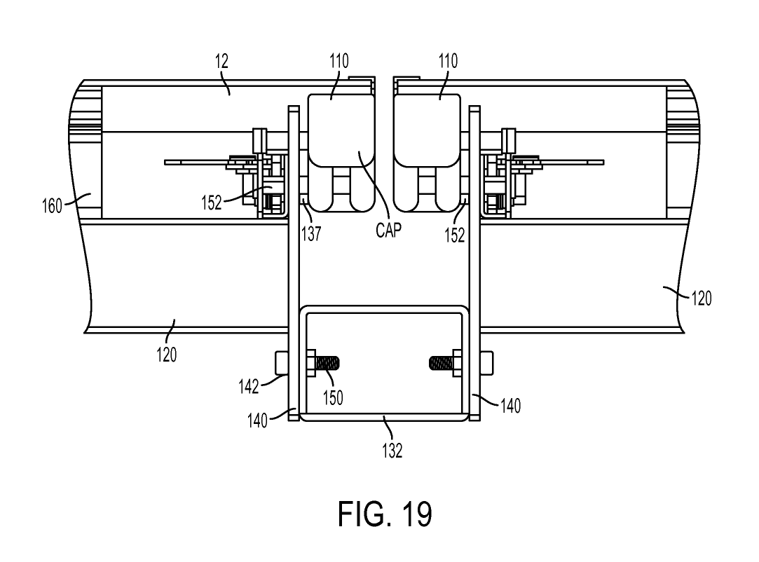

In an optional embodiment illustrated in FIGS. 12-18, the mounting system 100 comprises at least one of a means for selectively securing a pair of adjacently positioned panel modules 12 in an end-to-end relationship along a coupling axis, and a means for selectively securing a pair of adjacently positioned panel modules 12 to a support structure in an edge-to-edge relationship along a mounting axis that is transverse to the coupling axis. In another aspect, the mounting system and/or the means for selectively securing a pair of adjacently positioned panel modules in an end-to-end relationship and in an edge-to-edge relationship can comprise at least one of: a plurality of cell rails 110, a plurality of frame members 120, and a plurality of attachment devices 130.

As illustrated in FIGS. 12-15, the nearly square form of the assembly mounting system 100 eliminates the need for “landscape” versus “portrait” orientation installation decision and its modular constructions allows for easier installation with respect to pre-existing roof penetrations. Further, in one preferred example, the mounting system has a 48 inch horizontal dimension that works within conventional 16 inch or 24 inch center-to-center spacing of roof joists.

Optionally, the mounting system 100 can provide a means for module-to module interconnect wiring. In one aspect the means for module-to module interconnect wiring can be incorporated into the module frame system, which eliminates the need for wire clips, trays or other conventional wire-management add-ins while providing desired abrasion and animal control protection. In another aspect, and as shown and described in more detail below, the module to rail locking system can be configured to connect the frames electrically, which eliminates the need for grounding clips and conventional module to module grounding wires.

In the exemplary constructions illustrated in FIGS. 12-15, four conventional solar panels are supported by a mounting system 100 comprising the plurality of cell rails 110, the plurality of frame members 120, and the plurality of attachment devices 130. As shown, the plurality of attachment devices 130 comprises a plurality of mounting brackets 132 and a plurality of rail brackets 140 that can be selectively coupled to respective mounting brackets. In one aspect, each mounting bracket 132 has a substantially planar bottom surface 134 that defines openings 135 therethrough for passage of fixation means such as, for example and without limitation, roofing screws and the like so that the mounting brackets can be selectively fixed to the underlying surface. In another aspect, it is preferred that the mounting brackets 132 have a substantially rectangular hollow channel shape with the respective opposing side walls being substantially transverse to the bottom surface of the mounting bracket. The sides of the mounting bracket can define openings 136 for operative receipt of a connector.

In a further aspect, the rail brackets 140 can be a substantially planer member that has at least one opening 142 defined therein for operative receipt of the connector. As shown in the figures, coupling a rail bracket 140 to one side of the mounting bracket with a connector member 150 allows for the upper edge of the respective rail bracket to be elevated a desired first distance above the top surface of the mounting bracket. In a further aspect, the respective ends 122 of a frame member 120 can be coupled between two opposing rail brackets that are operable coupled, and transversely positioned with respect to, two spaced mounting brackets such that the upper surface of the frame member is spaced from the upper edges of the coupled rail brackets at a desired second distance that is greater than the first distance.

In another aspect, the upper portion of each rail bracket 140 defines a second opening 137 for receipt of a second connector 152. In this aspect, the end portions of the respective hollow cell rails 110 define openings 112 for operative receipt of the second connector. In operation, a respective cell rail is coupled to two opposing spaced mounting brackets via the second connector. In this aspect, the cell rail is positioned against and substantially parallel to a side surface of the respective rail bracket and is positioned substantially transverse to the frame member. Further, the cell rail is positioned above the top surface of the mounting bracket at a third desired distance that is greater than the first and second distances.

It is contemplated, as shown in the figures, that the rail brackets used for supporting panels can be sized and or can have openings positioned on them such that, as the elevation of the roof increases, the front edges of the adjoined solar panels can partially overlap the upper edge portion of the underlyingly positioned solar panels and be spaced a desired distance.

In a further aspect, the mounting system 100 can also comprise a plurality of elongated glass support members 160. Each elongated glass support member has an operable height that allows for the mounting on at least a portion of the upper surface of the frame members such that the top surface of each glass support member is positioned at a desired height relative to the top surface of the adjacent cell rails. In operation, a solar cell is positioned onto the respective top surfaces of two opposing glass support members and the respective top surfaces of two opposing cell rails. This operation would be repeated for each solar cell being mounted in the mounting system 100.

It will be apparent to those skilled in the art that various modifications and variations can be made in the present invention without departing from the scope or spirit of the invention. Other aspects of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A mounting system for mounting a plurality of solar panels, the mounting system comprising:
a plurality of panel modules, each panel module comprising a pair of elongate opposed mounting members configured to be arranged and secured spaced apart and substantially parallel to one another, wherein each of the mounting members is configured to receive and support an edge region of a solar panel such that one solar panel extends between the pair of opposed mounting members; and
at least one anchoring device configured to selectively secure a pair of adjacently positioned panel modules to an underlying support structure in an edge-to-edge relationship along a mounting axis, wherein each anchoring device comprises a footing adapted to be rigidly fastened to the underlying support structure, and a biasable support member having opposed outer ends configured for selective connection with a portion of respective outer mounting members of the pair of adjacently positioned panel modules, wherein the footing is coupled to the support member proximate a center point of the support member.

2. The mounting system of claim 1, wherein the center point of the support member substantially underlies respective inner mounting members of the pair of pair of adjacently positioned panel modules.

3. The mounting system of claim 2, wherein the center point of the support member is spaced from the respective inner mounting members of the pair of adjacently positioned panel modules, and wherein the anchoring device further comprises a center point support that is coupled to the center point of the support member and extends upwardly for selectively coupling to the respective inner mounting members of the pair of adjacently positioned panel modules.

4. The mounting system of claim 3, wherein the footing of the anchoring device comprises a footer plate that is configured for mounting the underlying structure and that has a upper surface that is configured for selectively fixed coupling of the center point support and the support member.

5. The mounting system of claim 1, wherein the support member has a leaf spring shape in which the respective outer ends of the support member extend upwardly with respect to the center point of the support member, and wherein respective outer ends of the support member can move under a bias constraint relative to the fixed center point of the support member.

6. The mounting system of claim 3, wherein the support member has a support coupling member at the respective outer ends of the support member that is configured to be selectively connectable with the respective outer mounting members along a portion of the length of the respective outer mounting members, wherein each mounting member has an elongate trough extending the substantial elongate length of the mounting member, and wherein each mounting member defines a coupling slot positioned between the proximal and distal ends of the mounting member, each coupling slot having a first coupling slot portion extending upwardly therefrom a bottom edge of the mounting member and a second coupling slot portion extending longitudinally from an end of the first coupling slot portion.

7. The mounting system of claim 6, wherein a distal end of each center point support has a pair of coupling male protrusions that extends outwardly from the opposing exterior surfaces of the center point support, each coupling male protrusion being configured to be selectively received therein the coupling slot of an adjoining inner mounting member, and wherein each coupling male protrusion is configured to form an interference fit with a portion of the second coupling slot portion when positioned in a coupled position.

8. The mounting system of claim 6, wherein each coupling member has a coupling male protrusion that extends outwardly from the exterior surfaces of the coupling member that is configured to be selectively received therein the coupling slot of an adjoining outer mounting member, and wherein the coupling male protrusion of the coupling member is configured to form an interference fit with a portion of the second coupling slot portion when positioned in a coupled position.

9. A mounting system of claim 1, further comprising a means for selectively locking a distal end of one pair of mounting members of one panel module to a proximal end of another pair of mounting members of an adjoining panel module to form at least a portion of one coupled panel module that is adjoined end-to-end along a coupling axis that is transverse to the mounting axis.

10. The mounting system of claim 9, wherein the means for selectively locking a distal end of one pair of mounting members of one panel module to a proximal end of another pair of mounting members of an adjoining panel module to form at least a portion of one coupled panel module comprises a selective locking mechanism coupled to each mounting member, the selective locking mechanism comprising:
an elongate trough extending the substantial elongate length of the mounting member;
a first elongate slot extending longitudinally inwardly from a distal end of the mounting member;
a second slot having a first slot portion extending upwardly therefrom a bottom edge of the mounting member and a second slot portion extending longitudinally inwardly from an end of the first slot portion, wherein the second slot is spaced a predetermined distance from the first slot and is positioned between the first slot and a proximal end of the mounting member; and
a mating bar being configured to be selectively fixedly received therein a portion of the trough of a mounting member, each mating bar comprising a pair of spaced first male protrusions extending outwardly from an outer surface of the mating bar, each first male protrusion of the mating bar being configured to be selectively received therein the first and second slots of an adjoining mounting member.

11. The mounting system of claim 10, wherein at least one first male protrusion is configured to form an interference fit with a portion of at least one of the first and second slots of the locking mechanism when the mating bar is positioned in a coupled position.

12. The mounting system of claim 11, wherein the first male protrusion that is configured to be received in the second slot is configured to form an interference fit with a portion of the second slot portion when the mating bar is positioned in the coupled position.

13. The mounting system of claim 10, wherein the selective locking mechanism further comprises:
a third elongate slot extending longitudinally inwardly from a proximal end of the mounting member; and
a fourth slot having a third slot portion extending upwardly therefrom a bottom edge of the mounting member and a fourth slot portion extending longitudinally inwardly from an end of the third slot portion, wherein the fourth slot is spaced the predetermined distance from the third slot and is positioned between the third slot and a distal end of the first slot, and
wherein the mating bar further comprises a pair of spaced second male protrusions extending outwardly from the outer surface of the mating bar, each second male protrusion of the mating bar being configured to be selectively received therein the third and fourth slots of another mounting member.

14. The mounting system of claim 13, wherein the mating bar has a first elongate portion and a second elongate portion, wherein the first elongate portion is parallel to the second elongate portion, and wherein an elongate axis of the first elongate portion is offset from an elongate axis of the second elongate portion by a predetermined offset distance, and wherein the first male protrusions extend from the first elongate portion and the second male protrusions extend from the second elongate portion.

15. The mounting system of claim 14, wherein the first male protrusions are offset from the second male protrusions by the predetermined offset distance.

16. The mounting system of claim 9, wherein, when selectively coupled, a lower edge of one solar panel overlaps an upper edge of the adjoined solar panel and wherein a lower edge of one solar panel is offset from the upper edge of the adjoined solar panel.

17. The mounting system of claim 1, wherein an electrical junction bus is formed at each end of the solar panel, and wherein the junction bus comprises one or more of a string-to-string bus, a bypass diode; a DC-to-DC converter or optimizer, or a DC-to-AC inverter.

18. The mounting system of claim 17, wherein each panel module further comprises a sub-array wiring assembly that is electrically coupled to the junction bus, and wherein at least a portion of the sub-array wiring assembly for each panel module is substantially enclosed in an inner cavity defined in at least one of the mounting members.

19. The mounting system of claim 18, wherein respective ends of the sub-array wiring assembly of respective adjoined panel modules are configured to be releasable and selectively electrically coupled.

20. A mounting system for mounting a plurality of solar panels, the mounting system comprising:
a plurality of panel modules, each panel module comprising a pair of elongate opposed mounting members configured to be arranged and secured spaced apart and substantially parallel to one another, wherein each of the mounting members is configured to receive and support an edge region of a solar panel such that one solar panel extends between the pair of opposed mounting members; and
a selective locking mechanism coupled to each mounting member that is configured to selectively lock distal ends of one pair of mounting members of one panel module to proximal ends of another pair of mounting members of an adjoining panel module to form at least a portion of one coupled panel module that is adjoined end-to-end along a coupling axis, wherein the selective locking mechanism comprises:
an elongate trough extending the substantial elongate length of each mounting member;
a first elongate slot extending longitudinally inwardly from a distal end of the mounting member;
a second slot having a first slot portion extending upwardly therefrom a bottom edge of the mounting member and a second slot portion extending longitudinally inwardly from an end of the first slot portion, wherein the second slot is spaced a predetermined distance from the first slot and is positioned between the first slot and a proximal end of the first slot; and
a mating bar being configured to be selectively fixedly received therein a portion of the trough of a mounting member, each mating bar having a pair of spaced first male protrusions extending outwardly from an outer surface of the mating bar, each first male protrusion of the mating bar being configured to be selectively received therein the first and second slots of an adjoining mounting member.

21. The mounting system of claim 20, wherein at least one first male protrusion is configured to form an interference fit with a portion of at least one of the first and second slots of the locking mechanism when the mating bar is positioned in a coupled position.

22. The mounting system of claim 20, wherein the first male protrusion that is configured to be received in the second slot is configured to form an interference fit with a portion of the second slot portion when the mating bar is positioned in the coupled position.

23. The mounting system of claim 20, wherein the selective locking mechanism further comprises:
a third elongate slot extending longitudinally inwardly from a proximal end of the mounting member; and
a fourth slot having a third slot portion extending upwardly therefrom a bottom edge of the mounting member and a fourth slot portion extending longitudinally inwardly from an end of the third slot portion, wherein the fourth slot is spaced the predetermined distance from the third slot and is positioned between the third slot and a distal end of the first slot, and
wherein the mating bar further comprises a pair of spaced second male protrusions extending outwardly from the outer surface of the mating bar, each second male protrusion of the mating bar being configured to be selectively received therein the third and fourth slots of another mounting member.

24. The mounting system of claim 23, wherein at least one second male protrusion is configured to form an interference fit with a portion of at least one of the third and fourth slots of the locking mechanism when the mating bar is positioned in a coupled position.

25. The mounting system of claim 23, wherein the mating bar has a first elongate portion and a second elongate portion, wherein the first elongate portion is parallel to the second elongate portion, and wherein an elongate axis of the first elongate portion is offset from an elongate axis of the second elongate portion by a predetermined offset distance.

26. The mounting system of claim 23, wherein the first male protrusions extend from the first elongate portion and the second male protrusions extend from the second elongate portion, and wherein the first male protrusions are offset from the second male protrusions by the predetermined offset distance.

27. The mounting system of claim 20, wherein, when selectively coupled, a bottom edge of one solar panel overlaps an upper edge of the adjoined solar panel.

28. The mounting system of claim 20, further comprising a means for selectively securing a pair of adjacently positioned panel modules to a support structure in an edge-to-edge relationship along a mounting axis that is transverse to the coupling axis.

29. The mounting system of claim 28, wherein the means for selectively securing a pair of adjacently positioned panel modules to a support structure comprises at least one anchoring device, wherein each anchoring device comprises a footing adapted to be rigidly fastened to an underlying support structure, and a biasable support member having opposed outer ends configured for selective connection with a portion of respective outer mounting members of the pair of adjacently positioned panel modules, and wherein the footing is coupled to the support member proximate the center point of the support member, wherein the center point of the support member substantially underlies respective inner mounting members of the pair of pair of adjacently positioned panel modules, and wherein the center point of the support member is spaced from the respective inner mounting members of the pair of adjacently positioned panel modules.

30. The mounting system of claim 29, wherein the anchoring device further comprises a center point support that is coupled to the center point of the support member and extends upwardly for selectively coupling to the respective inner mounting members of the pair of adjacently positioned panel modules, wherein the support member has a leaf spring shape in which the respective outer ends of the support member extend upwardly with respect to the center point of the support member, and wherein respective outer ends of the support member can move under a bias constraint relative to the fixed center point of the support structure.
